(19) United States
(12) Patent Application Publication
(10) Pub. No.: US 2026/0321336 A1
(43) Pub. Date: Oct. 15, 2026

(54) REPAIR SCHEME TESTING IN A MEMORY SYSTEM

(71) Applicant: Micron Technology, Inc., Boise, ID (US)

(72) Inventors: Alan J. Wilson, Boise, ID (US); Kevin G. Werhane, Kuna, ID (US)

(21) Appl. No.: 19/635,236

(22) Filed: Mar. 31, 2026

Related U.S. Application Data
(60) Provisional application No. 63/789,335, filed on Apr. 15, 2025.

(51) Int. Cl. G11C 29/44

(52) U.S. Cl. CPC G11C 29/4401

(57) ABSTRACT

Methods, systems, and devices for repair scheme testing in a memory system are described. A memory system may enter a test mode for testing a repair scheme of a memory system. The memory system may output a test mode flag based at least in part on entering the test mode. During the test mode flag, the memory system may also output a fuse flag that indicates a fuse that is reserved for the test mode and that is available for writing test data during the test mode. The memory system may store test data in the fuse based at least in part on the fuse being indicated by the fuse flag and based at least in part on being in the test mode for the repair scheme.

### CROSS REFERENCE

The present Application for Patent claims priority to U.S. Patent Application No. 63/789,335 by Wilson et al., entitled “REPAIR SCHEME TESTING IN A MEMORY SYSTEM,” filed Apr. 15, 2025, which is assigned to the assignee hereof, and which is expressly incorporated by reference in its entirety herein.

### TECHNICAL FIELD

The following relates to one or more systems for memory, including repair scheme testing in a memory system.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports repair scheme testing in a memory system in accordance with examples as disclosed herein.

FIG. 2 shows an example of a memory system that supports repair scheme testing in accordance with examples as disclosed herein.

FIG. 3 shows an example of a timing diagram that supports repair scheme testing in a memory system in accordance with examples as disclosed herein.

FIG. 4 shows an example of a process flow that supports repair scheme testing in a memory system in accordance with examples as disclosed herein.

FIG. 5 shows an example of a timing diagram that supports repair scheme testing in a memory system in accordance with examples as disclosed herein.

FIG. 6 shows an example of circuitry that supports repair scheme testing in a memory system in accordance with examples as disclosed herein.

FIG. 7 shows an example of a timing diagram that supports repair scheme testing in a memory system in accordance with examples as disclosed herein.

FIG. 8 shows a block diagram of a memory system that supports repair scheme testing in a memory system in accordance with examples as disclosed herein.

FIGS. 9 and 10 show flowcharts illustrating a method or methods that support repair scheme testing in a memory system in accordance with examples as disclosed herein.

### DETAILED DESCRIPTION

A memory system may use a repair scheme (e.g., a post package repair (PPR) scheme) that allows the memory system to “repair” defective rows within a memory array so that access operations addressed to a defective row are re-directed to a redundant (e.g., spare) row instead. To perform a repair for a defective row, the memory system stores the address of the faulty row in fuses or other non-volatile storage elements, then broadcasts the contents of the fuses to the banks of the memory array so that the appropriate bank can store the address in latches (referred to as a “repair latches”) corresponding to the redundant row for the repair.

Before operating a memory system in the field, the repair scheme may be tested by performing test repairs that “sacrifice” components for the repair scheme, such as fuses and redundant rows. For example, the fuses may be single-program storage elements which means that any fuse written with test data becomes unusable for actual repairs. Although the repair latches are not single-program storage elements, the circuitry used to write test data to the repair latches may not support subsequent writing of address information for defective rows, and so the corresponding redundant rows cannot be used for actual repairs after testing the repair scheme. In memory systems that have finite quantities of fuses and redundant rows reserved for the repair scheme, sacrificing these components for testing the repair scheme may reduce the quantity of available fuses and redundant rows for non-test repairs, and thus decrease the overall life of the memory system.

According to the techniques described herein, a memory system may test a repair scheme—without sacrificing fuses reserved for the repair scheme—by using extra fuses in a fuse array of the memory system, where an extra fuse is a fuse that is present in the memory system due to dimensioning and manufacturing constraints but is not necessarily reserved for the repair scheme or for operating the memory system. Further, the memory system may avoid sacrificing redundant rows by refraining from writing test data to the corresponding repair latches, or by writing test data to the repair latches using circuitry that allows subsequent writing of address information for defective rows.

In a first technique, the memory system may use a global (e.g., non-bank specific) test mode flag and an associated fuse selection signal to perform repair scheme testing. The test mode flag may indicate a first test mode in which one or more extra fuses indicated by the fuse selection signal are written (or “blown”) with test data. After writing the test data to the extra fuse(s), the memory system may read the extra fuse(s) and verify whether the content of the extra fuse(s) matches the test data. The first technique may avoid sacrificing redundant rows by avoiding storage of the fuse content (e.g., the test data) in the repair latches.

In a second technique, the memory system may use a bank-specific test mode flag and an associated fuse selection signal to perform repair scheme testing. Together with circuitry that is coupled with repair latches for a bank, the test mode flag and fuse selection signal may enable the memory system to store the content of extra fuses (previously written with test data) in the repair latches during a second test mode. The circuitry may be configured such that when the second test mode is exited, the repair latches can be overwritten with the addresses of defective rows, thus avoiding sacrificing the redundant rows. The test data may be a row address for a row that stores a first data pattern so that the memory system can perform a test repair by attempting to write a second data pattern to the row. The memory system may then verify whether the content of the row matches the first data pattern.

In addition to applicability in memory systems as described herein, techniques for repair scheme testing may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by preserving redundant rows, which may extend the life of electronic devices and thereby reduce electronic waste, among other benefits.

Features of the disclosure are illustrated and described in the context of systems and architectures. Features of the disclosure are further illustrated and described in the context of timing diagrams, circuitry, and flowcharts.

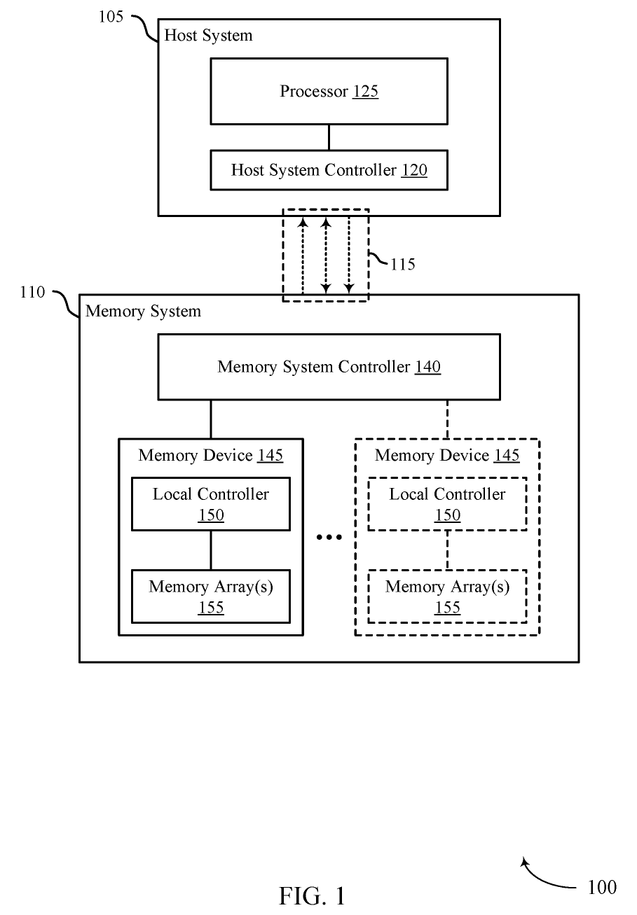

FIG. 1 shows an example of a system 100 that supports repair scheme testing in a memory system in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

The memory system 110 may implement a repair scheme (e.g., a PPR scheme) to repair defective rows (e.g., rows with one or more malfunctioning memory cells) with redundant rows. A defective row may also be referred to as a faulty row or other suitable terminology. Upon identifying a defective row, the memory system 110 may store the address of the defective row in fuses (or other one-time programmable non-volatile storage elements) so that the address is preserved in the event of a power loss. After storing the address in the fuses, the memory system 110 may broadcast the contents of the fuses to banks of the memory system 110 so that the appropriate bank can store the address in repair latches (or other volatile storage elements) that correspond to a redundant row. If a subsequent access operation targets the address of the defective row stored in the repair latches, the memory system 110 may use the corresponding redundant row (instead of the defective row) to perform the access operation.

It may be desirable to test the functionality of components that implement the repair scheme, which may be referred to as testing the repair scheme. But current techniques for testing the repair scheme may sacrifice components reserved for the repair scheme (e.g., fuses, redundant rows) because the memory system 110 is unable to overwrite (e.g., with defective row information) the test data stored in the components.

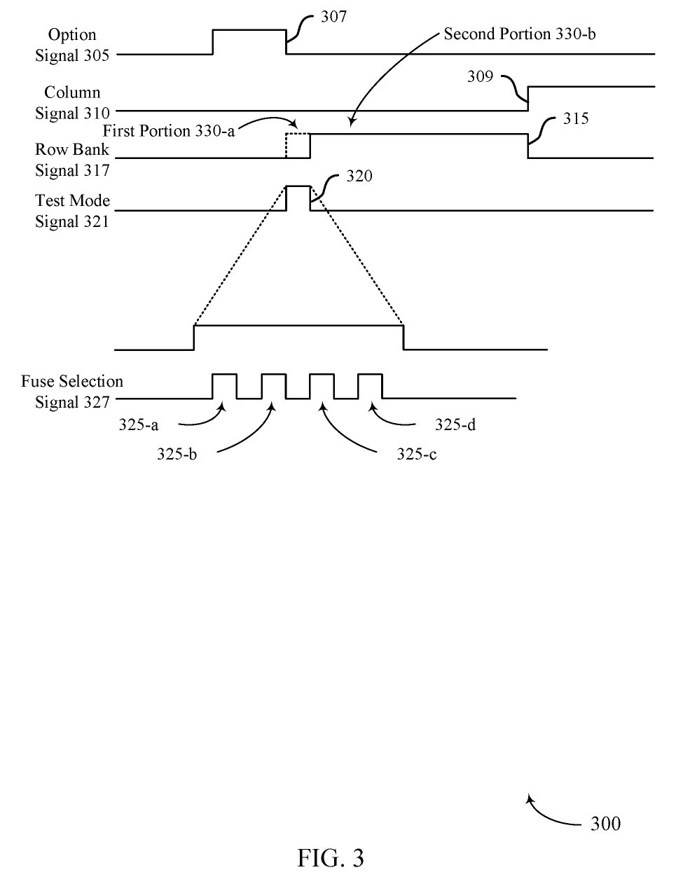

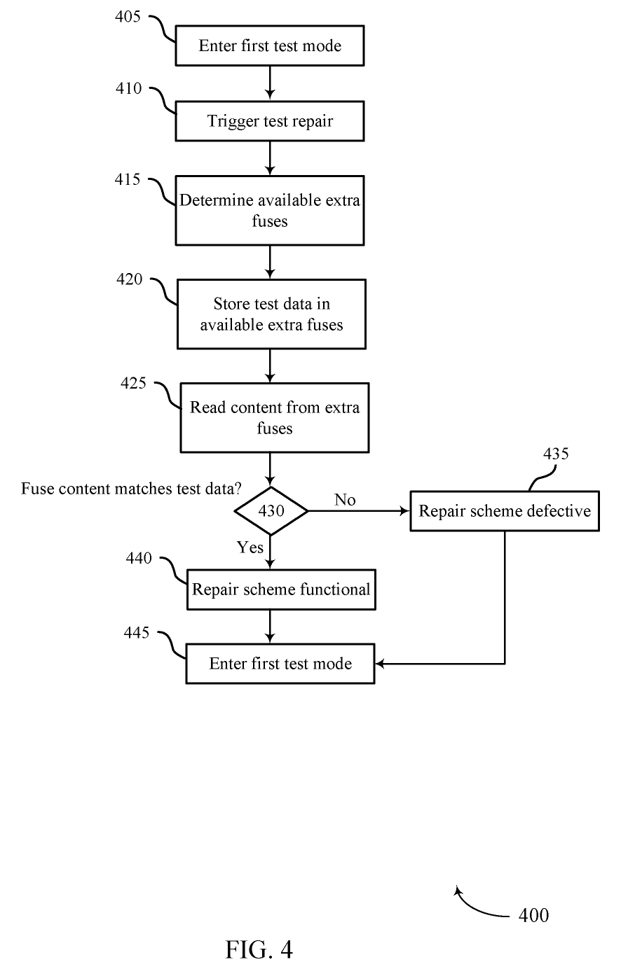

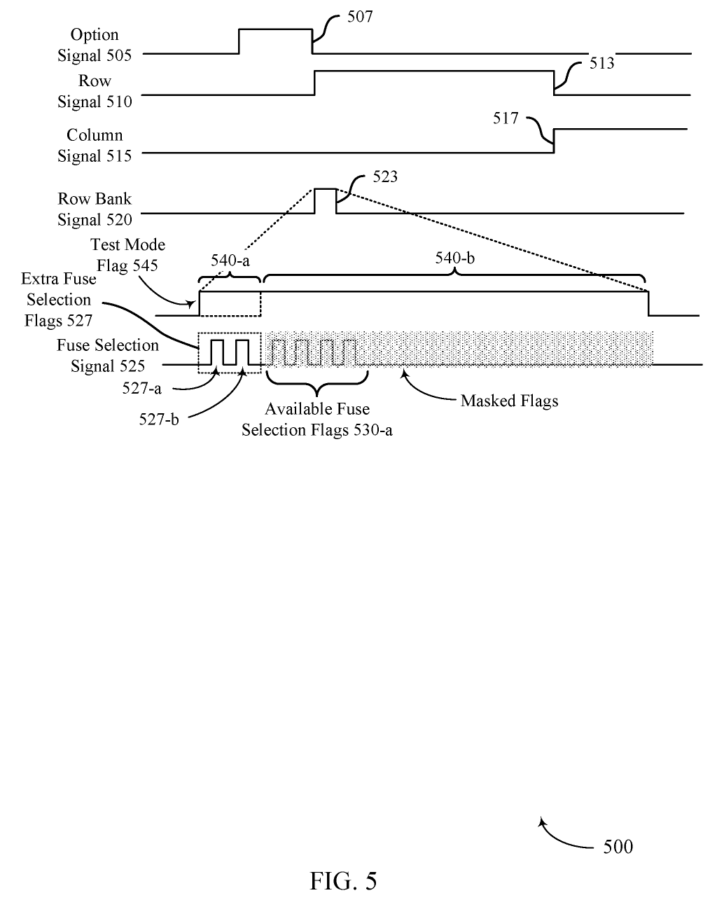

The memory system 110 may implement the techniques described herein to test a repair scheme without sacrificing components reserved for the repair scheme. In a first technique, described herein and with reference to FIGS. 3 and 4, the memory system 110 may avoid sacrificing fuses reserved for the repair scheme by using extra fuses for testing the repair scheme, and may avoid sacrificing redundant rows by using a first test mode that avoids storing test data from the extra fuses in the repair latches. In a second technique, described herein and with reference to FIGS. 5-7, the memory system 110 may avoid sacrificing fuses reserved for the repair scheme by using extra fuses for testing the repair scheme, and may avoid sacrificing redundant rows by using a second test mode and circuitry that enable the memory system 110 to overwrite (e.g., outside of the second test mode) test data in the repair latches. Although described separately, aspects of the first technique and second technique may overlap or be combined.

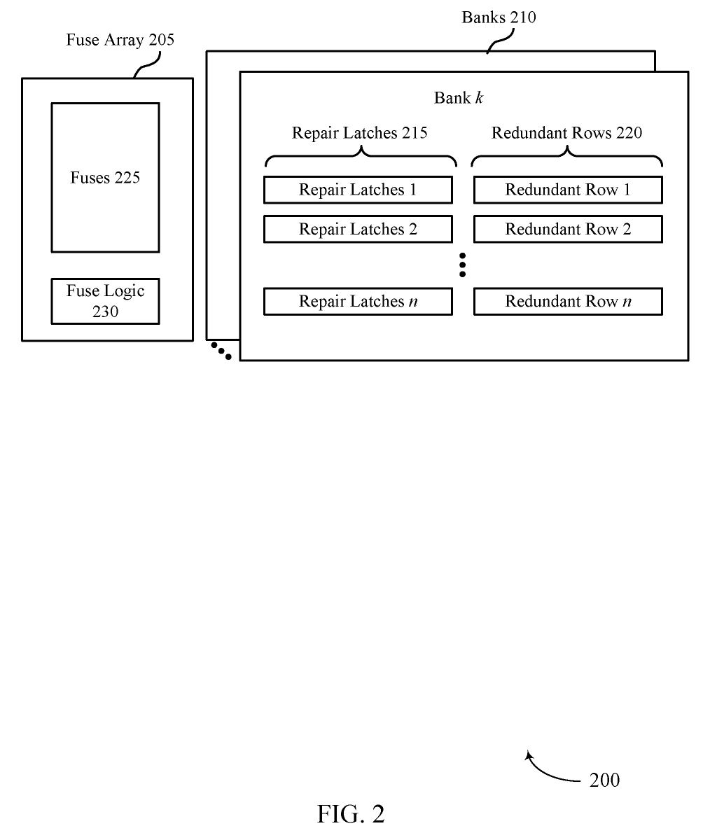

FIG. 2 illustrates an example of a memory system 200 that supports repair scheme testing in accordance with examples as disclosed herein. The memory system 200 may be an example of a memory system 110 described with reference to FIG. 1. The memory system 200 may include a fuse array 205 and banks 210, which may be memory banks included in one or more memory devices such as the memory devices 145 described with reference to FIG. 1. The memory system 200 may test the functionality of components (e.g., fuses 225, fuse logic 230, repair latches 215) that implement the repair scheme of the memory system 200 using the first technique, the second technique, or a combination thereof, as described herein. Use of the first technique, the second technique, or both may allow the memory system 200 to test the repair scheme without sacrificing any components reserved for the repair scheme.

The fuse array 205 may include fuses 225, which may be single-program (e.g., one-time programmable), non-volatile storage elements capable of storing one bit each. Together, a set of fuses 225 may be used to persistently store multi-bit information such as an address of a defective row (referred to as a defective address) or test data. The fuses 225 may be congregated in one area of the die or dispersed among the banks 210. Due to dimensioning and manufacturing constraints, the fuse array 205 may include extra fuses (e.g., fuses in excess of those used for operating the memory system 200). The extra fuses may be a group of fuses shared by the banks or may be groups of fuses that are bank-specific. According to the present disclosure, extra fuses may be reserved for the test modes so that during the test modes described herein, the extra fuses (instead of fuses that are reserved for the repair scheme) may be used to store test data. In this way, fuses reserved for actual (e.g., non-test) repairs may be preserved.

The fuse array 205 may include fuse logic 230 that is configured to operate and manage the fuse array 205 and to output (e.g., transmit to other components of the memory system 200) signals related to the fuse array 205. In some examples, the fuse logic 230 may include a finite state machine (FSM). The fuse array 205 may also include access circuitry, not shown, that performs write operations and read operations on the fuses 225 (e.g., as directed by the fuse logic 230).

The banks 210 may include one or more banks 210, including bank k. A bank 210 may include repair latches 215 and redundant rows 220. For example, bank k may include repair latches 1 through n and may include redundant rows 1 through n. Each set of repair latches 215 may have a corresponding redundant row 220 that is used for access operations that target the faulty address stored in that set of repair latches 215. For example, if the repair latches 1 store faulty address A, the memory system 200 may use redundant row 1 for access operations that target faulty address A. The faulty addresses stored in the repair latches 215 may be sourced from the fuses 225. For example, the faulty address stored in repair latches 1 may be from a set of fuses 225 that corresponds to repair latch 1.

The memory system 200 may test the repair scheme by storing test data in extra fuses of the fuse array 205. In the first technique, the memory system 200 may store the test data in the extra fuses during the first test mode, then check that the test data has been successfully stored by reading the extra fuses. If the test data has been successfully stored (e.g., if the content of the extra fuses matches the test data), the memory system 200 may determine that components for the repair scheme (e.g., the fuses 225, the fuse logic 230) are functional. Otherwise (e.g., if the content stored in the extra fuses does not match the test data), the memory system 200 may determine that one or more components for the repair scheme are defective. So, the first technique may allow the memory system 200 to test the functionality of the fuses 225 and the fuse logic 230. In the first technique, the extra fuses may not be associated with repair latches 215 (e.g., the extra fuses may be unassociated with the repair latches 215).

In the second technique, the memory system 200 may store test data (e.g., the row address for a random row) in the extra fuses during the second test mode, then transfer (e.g., using the circuitry 600) the test data from the extra fuses 225 to a repair latch 215. The memory system 200 may then check the repair scheme by performing a test repair for the row by attempting to overwrite a first data pattern stored by the row with a second data pattern. If, after the attempted repair, the content of the row matches the first data pattern, the memory system 200 may determine that the components for the repair scheme (e.g., the fuses 225, the fuse logic 230, the repair latches 215, the circuitry 600) are functional. Otherwise (e.g., if the content of the row matches the second data pattern), the memory system 200 may determine that one or more components for the repair scheme are defective. After checking the repair scheme, the memory system 200 may exit the second test mode and overwrite the test data in the repair latch 215 with a defective address. So, the second technique may allow the memory system 200 to test the functionality of the repair latches 215 and the circuitry 600 in addition to testing the functionality of the fuses 225 and the fuse logic 230.

In either technique, the test mode of the memory system 200 may be enabled by a mode register setting, test mode command, or other suitable mechanism.

FIG. 3 shows an example of a timing diagram 300 that supports repair scheme testing in a memory system in accordance with examples as disclosed herein. The timing diagram 300 may include various signals outputted by the fuse logic 230 as described with reference to FIG. 2. The signals may include an option signal 305, which may include option flag 307 that indicates one or more options for operating the memory system 200, a column signal 310, which may include a column flag 309 that indicates one or more columns of the memory system 200, and a row bank signal 317, which may include a row bank flag 315 that indicates a bank of the memory system 200. For example, a timing (e.g., temporal position) of the row bank flag 315 (e.g., relative to the option flag 307) may indicate a corresponding bank. The signals of the timing diagram 300 may be used internally within the fuse array 205 to manage the fuse array 205, may be outputted (e.g., broadcast) to the banks 210 of the memory system 200 to facilitate operations and modes such as the test modes described herein, or both.

The signals of the timing diagram 300 may also include a test mode signal 321, which may include a test mode flag 320 that indicates the first test mode. The test mode flag 320 may be a global (e.g., bank-agnostic) flag that is outputted based on the memory system 200 entering the first test mode. The signals of the timing diagram 300 may also include the fuse selection signal 327, which may include one or more fuse selection flags 325 that indicate respective sets of extra fuses that are reserved for the first test mode and available for use (are not yet programmed). For example, the timing of a fuse selection flag 325 relative to the test mode flag 320 may correspond to a respective set of extra fuses. As an illustration, the position of fuse selection flag 325-a may indicate a first set of extra fuses (Set A), the position of fuse selection flag 325-b may indicate a second set of extra fuses (Set B), the position of fuse selection flag 325-c may indicate a third set of extra fuses (Set C), and the position of fuse selection flag 325-d may indicate a fourth set of extra fuses (Set D).

If a set of extra fuses becomes unavailable (e.g., due to be programmed as part of testing the repair scheme), the corresponding fuse selection flag 325 may be omitted from the fuse selection signal 327. For example, if the first set of extra fuses (Set A) is programmed as part of testing the repair scheme, the corresponding fuse selection flag 325-a may be omitted from the fuse selection signal 327 (however, the fuse selection flags 325-b, 325-c, and 325-d may still be present).

In an alternative, the test mode flag may be a portion of the row bank signal 317 (instead of being a separate signal such as the test mode signal 321). For example, the row bank flag 315 may be extended so that the row bank flag 315 has a first portion 330-a followed by a second portion 330-b. In such an example, the timing of a fuse selection flag 325 relative to the first portion 330-a of the row bank flag 315 may correspond to a respective set of extra fuses.

Thus, the signals of the timing diagram 300 may be used to indicate the first test mode as well as sets of extra fuses that are available for storing test data during the first test mode.

FIG. 4 shows an example of a process flow 400 that supports repair scheme testing in a memory system in accordance with examples as disclosed herein. The process flow 400 may be implemented by a memory system such as the memory system 200 described with reference to FIG. 2. The process flow 400 may include operations that facilitate repair scheme testing using the first technique described herein.

At 405, the memory system may enter the first test mode. The memory system may enter the first test mode based on the first test mode being indicated by a mode register setting or by a test mode command. At 410, the memory system may trigger (e.g., request) a test repair for a row (e.g., a random row). The memory system may trigger the test repair based on entering the first test mode.

At 415, the memory system may determine available sets of extra fuses for performing the test repair. In some examples, the memory system may determine the available sets of extra fuses based on the test mode flag 320 and the fuse selection flags 325 as described with reference to FIG. 3. At 420, the memory system may store test data in a set of the available extra fuses. After storing the test data in the set of extra fuses, the memory system may refrain from storing the test data from the set of extra fuses in the repair latches of the memory system.

At 425, the memory system may read the content stored in the set of extra fuses. For example, the memory system may read the content via a fuse logic verify operation (e.g., in production testing) or via a mode register read (e.g., in the field before requesting actual repairs).

At 430, the memory system may determine whether the content from the set of extra fuses matches (e.g., is equal to) the test data. The memory system may determine a status of the repair scheme (e.g., a status of components that implement the repair scheme) based on the comparison. For example, if the content does not match the test data, the memory system may, at 435, determine that the components that implement the repair scheme are defective. If the content matches the test data, the memory system may, at 440, determine that the components that implement the repair scheme are functional (e.g., not defective). At 445, the memory system may exit the first test mode. During and after the first test mode, the memory system may refrain from storing the test data in the repair latches of the memory system, thus preserving the redundant rows for actual repairs.

Thus, the memory system may implement aspects of the process flow 400 to perform repair scheme testing using the first technique.

FIG. 5 shows an example of a timing diagram 500 that supports repair scheme testing in a memory system in accordance with examples as disclosed herein. The timing diagram 500 may include various signals outputted by the fuse logic 230 as described with reference to FIG. 2. The signals may include an option signal 505, which may include an option flag 507 that indicates one or more options for operating the memory system 200, a row signal 510, which may include a row flag 513 that indicates one or more rows of the memory system 200, a column signal 515, which may include a column flag 517 that indicates one or more columns of the memory system 200, and a row bank signal 520, which may include a row bank flag 523 that indicates one or more banks of the memory system 200. For example, a timing of the row bank flag 523 (e.g., relative to the row flag 513) may indicate a corresponding bank. In the given example, the row bank flag 523 may indicate bank k = 0. The signals of the timing diagram 500 may be used internally within the fuse array 205 to manage the fuse array 205, may be broadcast to the banks 210 of the memory system 200 to facilitate operations and modes such as the test modes described herein, or both.

The signals of the timing diagram 500 may include a test mode flag 545, which may indicate the second test mode. The test mode flag 545 may be a bank-specific flag that is outputted based on the memory system 200 entering the second test mode. The test mode flag 545 may be a first portion 540-a of the row bank signal 520 that includes the row bank flag 523. In such examples, the second portion 540-b of the row bank signal 520 may be the row bank flag 523.

The signals of the timing diagram 500 may also include the fuse selection signal 525, which may include one or more fuse selection flags 527 that indicate sets of extra fuses that are reserved for the second test mode and available for use, where an available set of extra fuses is a set of extra fuses that has yet to be programmed. For example, the timing of a fuse selection flag 527 relative to the test mode flag 545 may correspond to a respective set of extra fuses. As an illustration, the timing of fuse selection flag 527-a may indicate a first set of extra fuses (Set A), and the timing of fuse selection flag 527-b may indicate a second set of extra fuses (Set B).

The fuse selection signal 525 may also include fuse selection flags 530 that indicate fuse sets that are reserved for the repair scheme. The fuse selection flags 530 may include fuse selection flags 530-a that may indicate fuse sets that are available for the repair scheme. If a set of fuses becomes unavailable (e.g., due to be programmed as part of the repair scheme), the corresponding fuse selection flag 527 may be omitted from the fuse selection flag 527. While in the second test mode, the fuse selection flags 530 may be masked or otherwise ignored by the memory system.

Thus, the signals of the timing diagram 500 may be used to indicate the second test mode as well as sets of extra fuses that are available for storing test data during the second test mode. Although shown as being part of the row bank signal 520, the test mode flag 545 may be a separate signal as described with reference to FIG. 3.

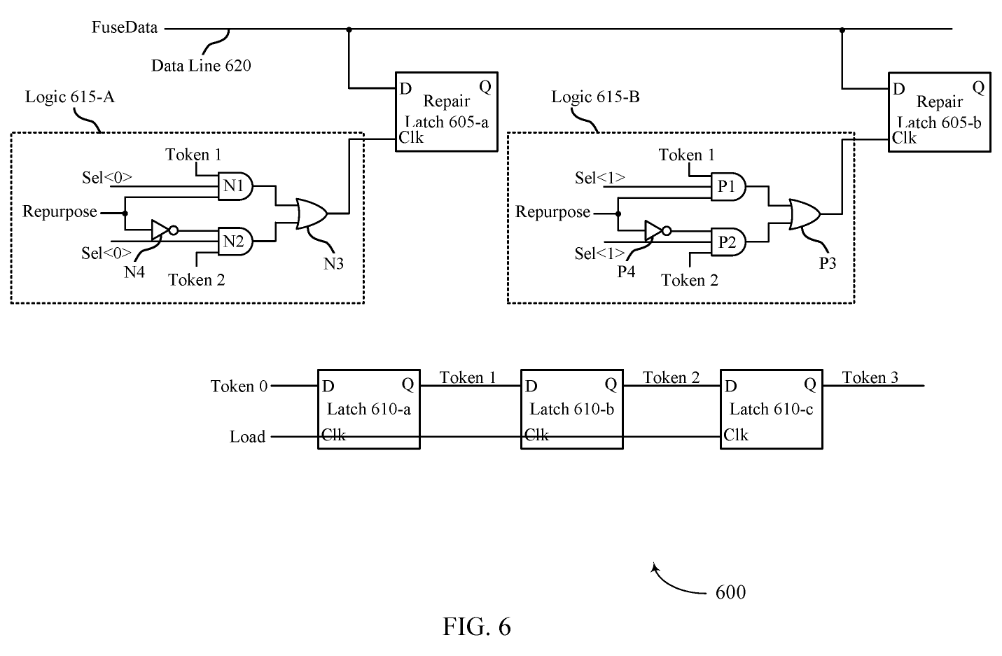

FIG. 6 shows an example of circuitry 600 that supports repair scheme testing in a memory system in accordance with examples as disclosed herein. The circuitry 600 may include repair latches 605, which may be examples of the repair latches 215 described with reference to FIG. 2. For example, the repair latch 605-a may be associated with a first redundant row and the repair latch 605-b may be associated with a second redundant row. The circuitry 600 may be configured so that test data stored in the repair latches 605 can be overwritten with the address information of defective rows. For example, the circuitry 600 may allow the memory system to store test data in the repair latches 605 during the second test mode, then store address information for defective rows outside of the second test mode (e.g., during a repair).

Such a technique may allow the repair scheme of the memory system to be tested without sacrificing the redundant rows corresponding to the repair latches used for the testing. For example, after writing test data to the repair latches 605, the content stored by the repair latches may be read out and compared with the test data. If the content matches the test data, the memory system may determine that components that implement the repair scheme are defective. If the content does not match the test data, the memory system may determine that components that implement the repair scheme are functional. Additionally or alternatively, if the test data is address information for a row that stores a first data pattern, the memory system may attempt a test repair for the row. If the content of the row after the test repair matches the second data pattern, the memory system may determine that components that implement the repair scheme are defective. If the content of the row after the test repair matches the first data pattern, the memory system may determine that components that implement the repair scheme are functional.

The repair latches 605 may be configured to store (or “latch”) information such as test data and address information for defective rows. For example, the repair latch 605-a may be configured to store first test data and first address information (e.g., at different times). And the repair latch 605-b may be configured to store second test data and second address information (e.g., at different times). A repair latch 605 may store (e.g., at output node Q) information inputted into input node D when a control signal (e.g., a token signal) is inputted into the clock node Clk. So, input of a token signal may control what information on the data line 620 is stored in the latches 605 (e.g., by controlling when the latches 605 are activated to store information).

The circuitry 600 may include latches 610, which may be flip-flop latches that pass along (e.g., output) control signals referred to as token signals. For example, latch 610-a may pass along Token 0 based on Token 1, latch 610-b may pass along Token 2 based on Token 1, and latch 610-c may pass along Token 3 based on Token 2. The token signals may be outputted at different times as shown in timing diagram 700, and each token signal may be associated with different information (denoted FuseData) on the data line 620. For example, Token 1 may be associated with test data (e.g., first test data, second test data) for the second test mode, whereas Token 2 may be associated with address information (e.g., first address information, second address information) for the repair scheme outside of the second test mode. The latches 610-a may pass on the token signals based on the load signal inputted into the clock inputs.

Referring to the timing diagram 700, the Fuse Data information during a first portion of Token 1 may be first test data from an extra fuse associated with fuse selection flag 527-a, and the Fuse Data information during a second portion of Token 1 may be second test data from a second extra fuses associated with fuse selection flag 527-b. The Fuse Data information during a first portion of Token 2 may be first address information (e.g., from a first fuse reserved for the repair scheme), and the Fuse Data information during a second portion of Token 2 may be second address information (e.g., from a second fuse reserved for the repair scheme).

The logic 615 may be configured to select between token signals to pass along (e.g., transfer) to the repair latches 605. For example, the logic 615-a may be configured to pass along (e.g., to repair latch 605-a) Token 1 based on the memory system being in the second test mode and may pass along (e.g., to repair latch 605-a) Token 2 based on the memory system being outside of the second test mode. When Token 1 is passed along, the repair latch 605-a stores the first test data (which may be present on the data line 620 during a first portion of Token 1). When Token 2 is passed along, the repair latch 605-a stores the first address information.

The logic 615-a may select between token signals based on the control signal Repurpose and the control signal Sel<0>. For example, the logic 615-a may pass along Token 1 when the control signal Repurpose is enabled (e.g., is a logic 1) and the control signal Sel<0> is enabled (e.g., is a logic 1). As illustrated in the timing diagram 700, the control signal Sel<0> may be enabled (or “asserted”) during the first portion of Token 1 so that the first test data is present on the data line 620 when the repair latch 605-a is activated in the second test mode. The logic 615-a may pass along Token 2 when the control signal Repurpose is disabled (e.g., is a logic 0) and the control signal Sel<0> is enabled (e.g., is a logic 1). The control signal Sel<0> may be enabled (or “asserted”) during the first portion of Token 2 so that the first address information is present on the data line 620 when the repair latch 605-a is activated in outside of the second test mode.

Thus, first test data (e.g., from an extra fuse associated with the fuse selection flag 527-a) may be stored in the repair latch 605-a, then overwritten with first address information for a first defective row.

The logic 615-a may include logic gates such as AND gate N1, AND gate N2, OR gate N3, and inverter N4, which may be coupled as illustrated in FIG. 6. The AND gate N1 may be configured to receive (at respective input nodes) Token 1, control signal Sel<0>, and control signal Repurpose. The OR gate N3 may be configured to pass along (e.g., output) either Token 1 or Token 2 to the clock input node of the repair latch 605-a.

The AND gate N1 may be configured to output (to a first input node of OR gate N3) Token 1 when the control signal Repurpose is enabled (e.g., is a logic 1) and the control signal Sel<0> is enabled (e.g., is a logic 1). Otherwise, the AND gate N1 may output a logic 0. The AND gate N2 may be configured to output (to a second input node of OR gate N3) Token 2 when the control signal Repurpose is disabled (e.g., is a logic 0) and the control signal Sel<0> is enabled (e.g., is a logic 1). Otherwise, the AND gate N2 may output a logic 0. The inverter N4 may be configured to invert the control signal Repurpose so that only one of AND gate N1 and AND gate N2 output a token signal when the control signal Sel<0> is enabled.

The logic 615-b may be similar to the logic 615-a except that the logic 615-b receive control signal Sel<1> instead of control signal Sel<0>. Further, the logic 615-b may be configured to cause the repair latch 605-b to store (e.g., at different times) second test data (e.g., from an extra fuse associated with fuse selection flag 527-n) and second address information for a second defective row.

The logic 615-b may be configured to pass along (e.g., to repair latch 605-b) Token 1 based on the memory system being in the second test mode and may pass along (e.g., to repair latch 605-b) Token 2 based on the memory system being outside of the second test mode. When Token 1 is passed along, the repair latch 605-b stores the second test data (which may be present on the data line 620 during a second portion of Token 1). When Token 2 is passed along, the repair latch 605-b stores the second address information.

The logic 615-b may select between token signals based on the control signal Repurpose and the control signal Sel<1>. For example, the logic 615-b may pass along Token 1 when the control signal Repurpose is enabled (e.g., is a logic 1) and the control signal Sel<1> is enabled (e.g., is a logic 1). As illustrated in the timing diagram 700, the control signal Sel<1> may be enabled (or “asserted”) during the second portion of Token 1 so that the second test data is present on the data line 620 when the repair latch 605-b is activated in the second test mode. The logic 615-b may pass along Token 2 when the control signal Repurpose is disabled (e.g., is a logic 0) and the control signal Sel<1> is enabled (e.g., is a logic 1). The control signal Sel<1> may be enabled (or “asserted”) during the second portion of Token 2 so that the second address information is present on the data line 620 when the repair latch 605-b is activated in outside of the second test mode.

Thus, second test data (e.g., from an extra fuse associated with the fuse selection flag 527-b) may be stored in the repair latch 605-b, then overwritten with second address information for a second defective row.

The logic 615-b may include logic gates such as AND gate P1, AND gate P2, OR gate P3, and inverter P4, which may be coupled as illustrated in FIG. 6. The AND gate P1 may be configured to receive (at respective input nodes) Token 1, control signal Sel<1>, and control signal Repurpose. The OR gate P3 may be configured to pass along (e.g., output) either Token 1 or Token 2 to the clock input node of the repair latch 605-b.

The AND gate P1 may be configured to output (to a first input node of OR gate P3) Token 1 when the control signal Repurpose is enabled (e.g., is a logic 1) and the control signal Sel<1> is enabled (e.g., is a logic 1). Otherwise, the AND gate P1 may output a logic 0. The AND gate P2 may be configured to output (to a second input node of OR gate P3) Token 2 when the control signal Repurpose is disabled (e.g., is a logic 0) and the control signal Sel<1> is enabled (e.g., is a logic 1). Otherwise, the AND gate P2 may output a logic 0. The inverter P4 may be configured to invert the control signal Repurpose so that only one of AND gate P1 and AND gate P2 output a token signal when the control signal Sel<1> is enabled.

Thus, the circuitry 600 may allow the memory system to store test data in the repair latches 605 during the second test mode, then store address information for defective rows outside of the second test mode (e.g., during a repair).

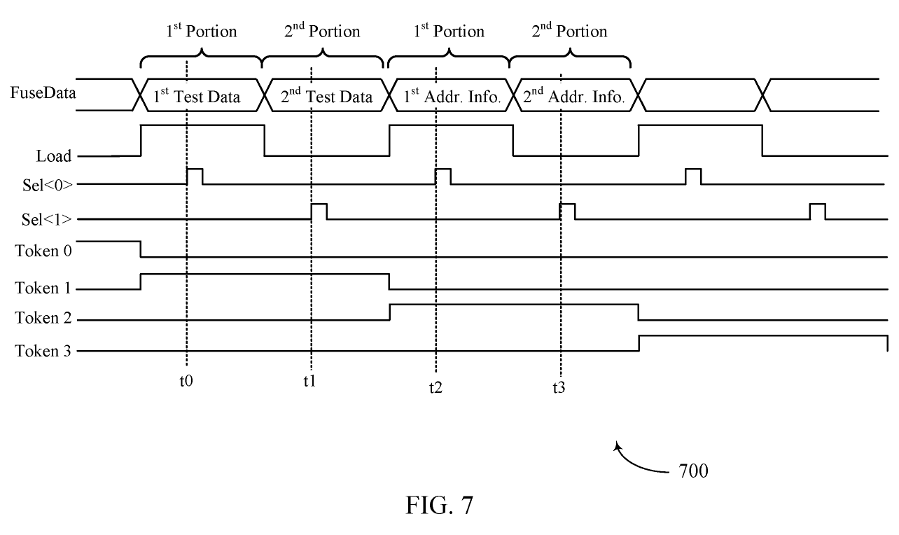

FIG. 7 shows an example of a timing diagram 700 that supports repair scheme testing in a memory system in accordance with examples as disclosed herein. The timing diagram 700 may include signals use to operate the circuitry 600 as described with reference to FIG. 6. For example, the timing diagram 700 may include the FuseData signal on the data line 620, which may convey different data at different times. The timing diagram 700 may also include the Load signal used to activate the latches 610. The timing diagram may also include the control signals Sel<0> and Sel<1>, as well as the token signals Token 0, Token 1, Token 2, and Token 3. The signal of the timing diagram 700 may enable storage of test data and address information in the repair latches 605 as described with reference to FIG. 6.

As seen in the timing diagram 700, the token signals may be asserted (e.g., outputted by the latches 610) at different times in a cascade manner. For example, Token 0 may be asserted, followed by Token 1, followed by Token 3. The FuseData signal may convey two different sets of information per token signal. For example, during a first portion of Token 1, the FuseData signal may represent first test data from an extra fuse associated with the extra set of fuses indicated by the fuse selection flag 527-a. During a second portion of Token 1, the FuseData signal may represent second test data from an extra fuse associated with the extra set of fuses indicated by the fuse selection flag 527-b. During a first portion of Token 2, the FuseData signal may represent first address data associated with a first defective row. During a second portion of Token 2, the FuseData signal may represent second address data associated with a second defective row.

At time t0, during assertion of Token 1 and based on the assertion of the control signal Sel<0>, the repair latch 605-a may store the first test data conveyed by the data line 620. At time t1, during assertion of Token 1 and based on the assertion of the control signal Sel<1>, the repair latch 605-b may store the second test data conveyed by the data line 620. Time t0 and time t1 may occur during the second test mode.

At time t2, during assertion of Token 2 and based on the assertion of the control signal Sel<0>, the repair latch 605-a may store the first address data conveyed by the data line 620. At time t3, during assertion of Token 2 and based on the assertion of the control signal Sel<1>, the repair latch 605-b may store the second address data conveyed by the data line 620. Time t2 and time t3 may occur outside of the second test mode.

Thus, the signals of the timing diagram 700 may be used to operate the circuitry 600 so that test data can be written to the repair latches during the second test mode for testing the repair scheme, then overwritten with address information outside of the second test mode.

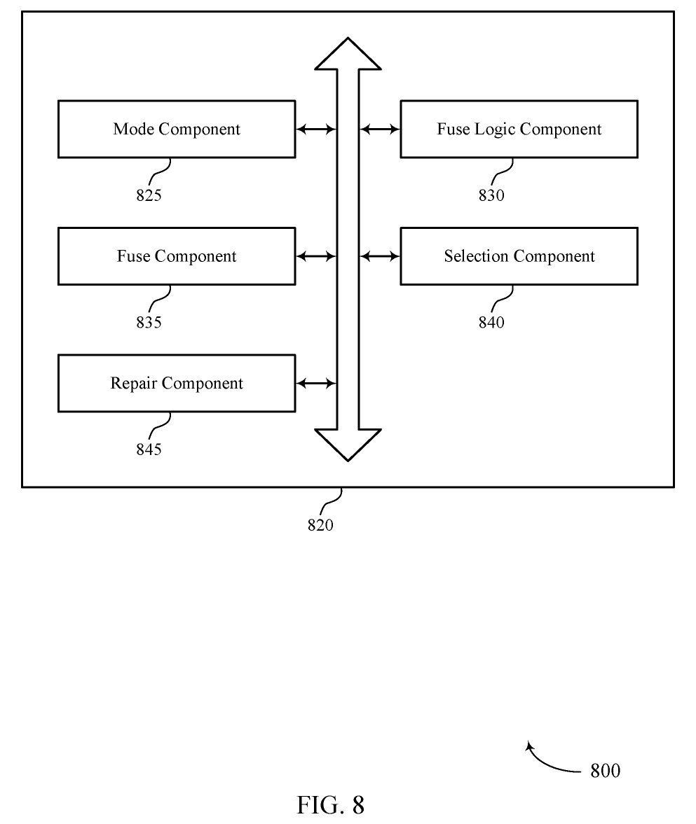

FIG. 8 shows a block diagram 800 of a memory system 820 that supports repair scheme testing in a memory system in accordance with examples as disclosed herein. The memory system 820 may be an example of aspects of a memory system as described with reference to FIGS. 1-7. The memory system 820, or various components thereof, may be an example of means for performing (e.g., to cause the memory system 820 to perform) various aspects of repair scheme testing in a memory system as described herein. For example, the memory system 820 may include a mode component 825, a fuse logic component 830, a fuse component 835, a selection component 840, a repair component 845, or any combination thereof. Each of these components, or components of subcomponents thereof (e.g., one or more processors, one or more memories), may communicate, directly or indirectly, with one another (e.g., via one or more buses).

The mode component 825 may be configured as or otherwise support a means for entering a test mode for testing a repair scheme of a memory system, where the repair scheme replaces a defective row of the memory system with a redundant row of the memory system. The fuse logic component 830 may be configured as or otherwise support a means for outputting a test mode flag based at least in part on entering the test mode. In some examples, the fuse logic component 830 may be configured as or otherwise support a means for outputting, during outputting of the test mode flag, a fuse flag that indicates a fuse that is reserved for the test mode and that is available for writing test data during the test mode. The fuse component 835 may be configured as or otherwise support a means for storing test data in the fuse based at least in part on the fuse being indicated by the fuse flag and based at least in part on being in the test mode for the repair scheme.

In some examples, the memory system includes repair latches for the repair scheme, and the repair component 845 may be configured as or otherwise support a means for refraining from storing the test data in the repair latches of the memory system based at least in part on being in the test mode.

In some examples, the fuse logic component 830 may be configured as or otherwise support a means for outputting an indication of non-test fuses that are available for the repair scheme, where the test data is stored in the fuse instead of the non-test fuses based at least in part on the test mode flag.

In some examples, a timing of the fuse flag relative to the test mode flag indicates the fuse.

In some examples, the fuse component 835 may be configured as or otherwise support a means for reading the fuse based at least in part on storing the test data in the fuse. In some examples, the fuse component 835 may be configured as or otherwise support a means for determining a status of the repair scheme based at least in part on reading the fuse.

In some examples, to support determining the status of the repair scheme, the repair component 845 may be configured as or otherwise support a means for determining that components that implement the repair scheme are defective based at least in part on content read from the fuse being different than the test data.

In some examples, to support determining the status of the repair scheme, the repair component 845 may be configured as or otherwise support a means for determining that components that implement the repair scheme are functional based at least in part on content read from the fuse matching the test data.

In some examples, the fuse logic component 830 may be configured as or otherwise support a means for outputting a row flag that indicates a row of memory cells in the memory system, where the test mode flag is different than the row flag.

In some examples, the test mode flag includes a first portion of a signal. In some examples, a row flag includes a second portion of the signal that is outputted after the first portion, the row flag indicating a row of memory cells in the memory system.

In some examples, the mode component 825 may be configured as or otherwise support a means for entering a test mode for testing a repair scheme of a memory system, where the repair scheme includes replacing a defective row of the memory system with a redundant row of the memory system. In some examples, the fuse component 835 may be configured as or otherwise support a means for storing, based at least in part on entering the test mode, test data in a fuse reserved for the test mode. The selection component 840 may be configured as or otherwise support a means for selecting, for passing to a repair latch corresponding to the redundant row and based at least in part on being in the test mode, between a first token signal outputted by a first latch and a second token signal outputted by a second latch. The repair component 845 may be configured as or otherwise support a means for storing the test data from the fuse in the repair latch based at least in part on passing the first token signal to the repair latch.

In some examples, the fuse component 835 may be configured as or otherwise support a means for outputting the test data from the fuse to the repair latch corresponding to the redundant row of the memory system based at least in part on being in the test mode.

In some examples, the repair component 845 may be configured as or otherwise support a means for storing, in the repair latch, an address of the defective row based at least in part on exiting the test mode, where storing the address overwrites the test data in the repair latch.

In some examples, the selection component 840 may be configured as or otherwise support a means for selecting, after selecting the first token signal, the second token signal to pass to the repair latch, where the address is stored in the repair latch based at least in part on passing the first token signal to the repair latch.

In some examples, the first token signal is inputted into a clock input terminal of the repair latch based at least in part on selecting the first token signal. In some examples, the test data is stored in the repair latch based at least in part on inputting the first token signal into the repair latch.

In some examples, the first token signal is selected by logic coupled with the first latch, and the selection component 840 may be configured as or otherwise support a means for receiving, by the logic, a first control signal that indicates the test mode, where the first token signal is selected based at least in part on receiving the first control signal. In some examples, the first token signal is selected by logic coupled with the first latch, and the selection component 840 may be configured as or otherwise support a means for receiving, by the logic, a second control signal that indicates the fuse, where the first token signal is selected based at least in part on receiving the second control signal.

In some examples, the described functionality of the memory system 820, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements) that are configured to cause the memory system 820 to perform one or more operations. In some examples, the described functionality of the memory system 820, or various components thereof, may be implemented at least in part by instructions (e.g., stored in memory, non-transitory computer-readable medium) executable by such at least one processor to cause the memory system 820 to perform one or more operations.

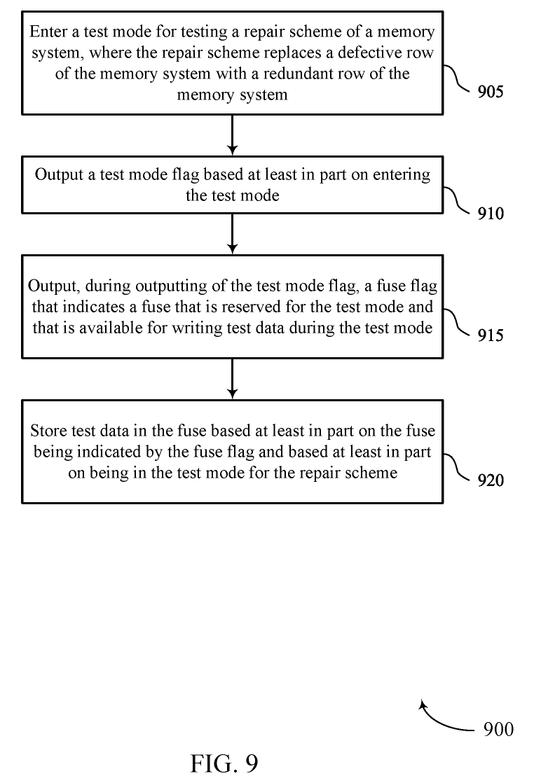

FIG. 9 shows a flowchart illustrating a method 900 that supports repair scheme testing in a memory system in accordance with examples as disclosed herein. The operations of method 900 may be implemented by a memory system or its components as described herein. For example, the operations of method 900 may be performed by a memory system as described with reference to FIGS. 1-8. In some examples, a memory system may execute a set of instructions to control the functional elements of the device to perform the described functions. Additionally, or alternatively, the memory system may perform aspects of the described functions using special-purpose hardware.

At 905, the method may include entering a test mode for testing a repair scheme of a memory system, where the repair scheme replaces a defective row of the memory system with a redundant row of the memory system. In some examples, aspects of the operations of 905 may be performed by a mode component 825.

At 910, the method may include outputting a test mode flag based at least in part on entering the test mode. In some examples, aspects of the operations of 910 may be performed by a fuse logic component 830.

At 915, the method may include outputting, during outputting of the test mode flag, a fuse flag that indicates a fuse that is reserved for the test mode and that is available for writing test data during the test mode. In some examples, aspects of the operations of 915 may be performed by a fuse logic component 830.

At 920, the method may include storing test data in the fuse based at least in part on the fuse being indicated by the fuse flag and based at least in part on being in the test mode for the repair scheme. In some examples, aspects of the operations of 920 may be performed by a fuse component 835.

In some examples, an apparatus as described herein may perform a method or methods, such as the method 900. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for entering a test mode for testing a repair scheme of a memory system, where the repair scheme replaces a defective row of the memory system with a redundant row of the memory system; outputting a test mode flag based at least in part on entering the test mode; outputting, during outputting of the test mode flag, a fuse flag that indicates a fuse that is reserved for the test mode and that is available for writing test data during the test mode; and storing test data in the fuse based at least in part on the fuse being indicated by the fuse flag and based at least in part on being in the test mode for the repair scheme.

Aspect 2: The method, apparatus, or non-transitory computer-readable medium of aspect 1, where the memory system includes repair latches for the repair scheme and the method, apparatuses, and non-transitory computer-readable medium further includes operations, features, circuitry, logic, means, or instructions, or any combination thereof for refraining from storing the test data in the repair latches of the memory system based at least in part on being in the test mode.

Aspect 3: The method, apparatus, or non-transitory computer-readable medium of any of aspects 1 through 2, further including operations, features, circuitry, logic, means, or instructions, or any combination thereof for outputting an indication of non-test fuses that are available for the repair scheme, where the test data is stored in the fuse instead of the non-test fuses based at least in part on the test mode flag.

Aspect 4: The method, apparatus, or non-transitory computer-readable medium of any of aspects 1 through 3, where a timing of the fuse flag relative to the test mode flag indicates the fuse.

Aspect 5: The method, apparatus, or non-transitory computer-readable medium of any of aspects 1 through 4, further including operations, features, circuitry, logic, means, or instructions, or any combination thereof for reading the fuse based at least in part on storing the test data in the fuse and determining a status of the repair scheme based at least in part on reading the fuse.

Aspect 6: The method, apparatus, or non-transitory computer-readable medium of aspect 5, where determining the status of the repair scheme includes operations, features, circuitry, logic, means, or instructions, or any combination thereof for determining that components that implement the repair scheme are defective based at least in part on content read from the fuse being different than the test data.

Aspect 7: The method, apparatus, or non-transitory computer-readable medium of any of aspects 5 through 6, where determining the status of the repair scheme includes operations, features, circuitry, logic, means, or instructions, or any combination thereof for determining that components that implement the repair scheme are functional based at least in part on content read from the fuse matching the test data.

Aspect 8: The method, apparatus, or non-transitory computer-readable medium of any of aspects 1 through 7, further including operations, features, circuitry, logic, means, or instructions, or any combination thereof for outputting a row flag that indicates a row of memory cells in the memory system, where the test mode flag is different than the row flag.

Aspect 9: The method, apparatus, or non-transitory computer-readable medium of any of aspects 1 through 8, where the test mode flag includes a first portion of a signal and a row flag includes a second portion of the signal that is outputted after the first portion, the row flag indicating a row of memory cells in the memory system.

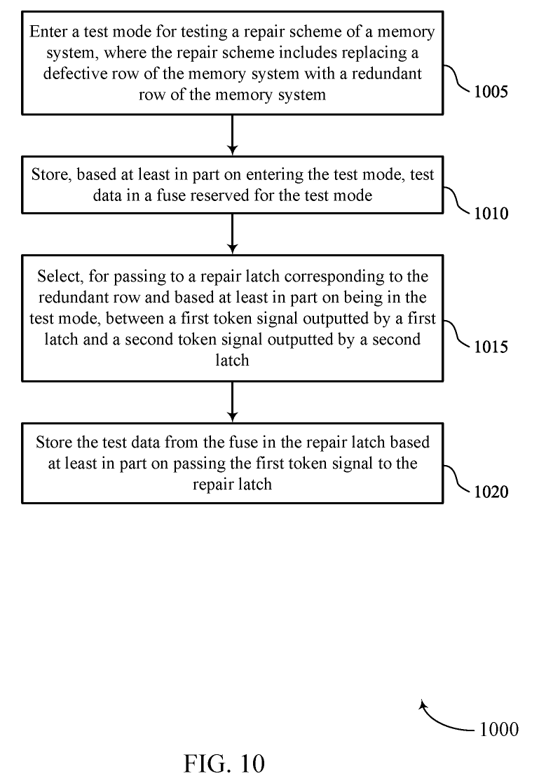

FIG. 10 shows a flowchart illustrating a method 1000 that supports repair scheme testing in a memory system in accordance with examples as disclosed herein. The operations of method 1000 may be implemented by a memory system or its components as described herein. For example, the operations of method 1000 may be performed by a memory system as described with reference to FIGS. 1-8. In some examples, a memory system may execute a set of instructions to control the functional elements of the device to perform the described functions. Additionally, or alternatively, the memory system may perform aspects of the described functions using special-purpose hardware.

At 1005, the method may include entering a test mode for testing a repair scheme of a memory system, where the repair scheme includes replacing a defective row of the memory system with a redundant row of the memory system. In some examples, aspects of the operations of 1005 may be performed by a mode component 825.

At 1010, the method may include storing, based at least in part on entering the test mode, test data in a fuse reserved for the test mode. In some examples, aspects of the operations of 1010 may be performed by a fuse component 835.

At 1015, the method may include selecting, for passing to a repair latch corresponding to the redundant row and based at least in part on being in the test mode, between a first token signal outputted by a first latch and a second token signal outputted by a second latch. In some examples, aspects of the operations of 1015 may be performed by a selection component 840.

At 1020, the method may include storing the test data from the fuse in the repair latch based at least in part on passing the first token signal to the repair latch. In some examples, aspects of the operations of 1020 may be performed by a repair component 845.

In some examples, an apparatus as described herein may perform a method or methods, such as the method 1000. The apparatus may include features, circuitry, logic, means, or instructions (e.g., a non-transitory computer-readable medium storing instructions executable by a processor), or any combination thereof for performing the following aspects of the present disclosure:

Aspect 10: A method, apparatus, or non-transitory computer-readable medium including operations, features, circuitry, logic, means, or instructions, or any combination thereof for entering a test mode for testing a repair scheme of a memory system, where the repair scheme includes replacing a defective row of the memory system with a redundant row of the memory system; storing, based at least in part on entering the test mode, test data in a fuse reserved for the test mode; selecting, for passing to a repair latch corresponding to the redundant row and based at least in part on being in the test mode, between a first token signal outputted by a first latch and a second token signal outputted by a second latch; and storing the test data from the fuse in the repair latch based at least in part on passing the first token signal to the repair latch.

Aspect 11: The method, apparatus, or non-transitory computer-readable medium of aspect 10, further including operations, features, circuitry, logic, means, or instructions, or any combination thereof for outputting the test data from the fuse to the repair latch corresponding to the redundant row of the memory system based at least in part on being in the test mode.

Aspect 12: The method, apparatus, or non-transitory computer-readable medium of any of aspects 10 through 11, further including operations, features, circuitry, logic, means, or instructions, or any combination thereof for storing, in the repair latch, an address of the defective row based at least in part on exiting the test mode, where storing the address overwrites the test data in the repair latch.

Aspect 13: The method, apparatus, or non-transitory computer-readable medium of aspect 12, further including operations, features, circuitry, logic, means, or instructions, or any combination thereof for selecting, after selecting the first token signal, the second token signal to pass to the repair latch, where the address is stored in the repair latch based at least in part on passing the first token signal to the repair latch.

Aspect 14: The method, apparatus, or non-transitory computer-readable medium of any of aspects 10 through 13, where the first token signal is inputted into a clock input terminal of the repair latch based at least in part on selecting the first token signal and the test data is stored in the repair latch based at least in part on inputting the first token signal into the repair latch.

Aspect 15: The method, apparatus, or non-transitory computer-readable medium of any of aspects 10 through 14, where the first token signal is selected by logic coupled with the first latch and the method, apparatuses, and non-transitory computer-readable medium further includes operations, features, circuitry, logic, means, or instructions, or any combination thereof for receiving, by the logic, a first control signal that indicates the test mode, where the first token signal is selected based at least in part on receiving the first control signal and receiving, by the logic, a second control signal that indicates the fuse, where the first token signal is selected based at least in part on receiving the second control signal.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 16: A memory system, including: a repair latch associated with a redundant row of the memory system; a first latch configured to output a first token signal; a second latch configured to output a second token signal based at least in part on the first token signal; and logic coupled with the first latch and the second latch and configured to select between the first token signal or the second token signal to pass to the repair latch, where the repair latch is configured to store an address for a defective row or test data based at least in part on the first token signal or the second token signal selected by the logic.

Aspect 17: The memory system of aspect 16, where the logic includes: a first logic gate configured to receive the first token signal, a first control signal that indicates a test mode for a repair scheme, and a second control signal that indicates a fuse that stores the test data for the repair scheme.

Aspect 18: The memory system of aspect 17, where the logic includes: a second logic gate configured to receive the second token signal, an inversion of the first control signal that indicates the test mode, and the second control signal that indicates the fuse.

Aspect 19: The memory system of aspect 18, where the logic includes: an OR gate including a first input node coupled with an output node of the first logic gate, and including a second input node coupled with an output node of the second logic gate.

Aspect 20: The memory system of any of aspects 18 through 19, where the first logic gate includes a first AND gate, and the second logic gate includes a second AND gate.

Aspect 21: The memory system of any of aspects 16 through 20, further including: second logic coupled with the first latch and the second latch and configured to select between the first token signal and the second token signal to pass to a second repair latch, where the second repair latch is configured to store a second address for a second defective row or second test data based at least in part on the first token signal or the second token signal selected by the second logic.

Aspect 22: The memory system of any of aspects 16 through 21, further including: a data line coupled with a data input node of the repair latch, the data line configured to convey the test data and the address at different times.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
processing circuitry associated with one or more memory devices and configured to cause the memory system to:
enter a test mode for testing a repair scheme of the memory system, wherein the repair scheme replaces a defective row of the memory system with a redundant row of the memory system;
output a test mode flag based at least in part on entering the test mode;
outputting, during outputting of the test mode flag, a fuse flag that indicates a fuse that is reserved for the test mode and that is available for writing test data during the test mode; and
store test data in the fuse based at least in part on the fuse being indicated by the fuse flag and based at least in part on being in the test mode for the repair scheme.

2. The memory system of claim 1, wherein the memory system comprises repair latches for the repair scheme, wherein the fuse is unassociated with the repair latches, and wherein the processing circuitry is further configured to cause the memory system to:
refrain from storing the test data in the repair latches of the memory system based at least in part on being in the test mode.

3. The memory system of claim 1, wherein the processing circuitry is further configured to cause the memory system to:
output an indication of non-test fuses that are available for the repair scheme, wherein the test data is stored in the fuse instead of the non-test fuses based at least in part on the test mode flag.

4. The memory system of claim 1, wherein a timing of the fuse flag relative to the test mode flag indicates the fuse.

5. The memory system of claim 1, wherein the processing circuitry is further configured to cause the memory system to:
reading the fuse based at least in part on storing the test data in the fuse; and
determining a status of the repair scheme based at least in part on reading the fuse.

6. The memory system of claim 5, wherein the processing circuitry is configured to cause the memory system to determine the status of the repair scheme by being configured to cause the memory system to:
determine that components that implement the repair scheme are defective based at least in part on content read from the fuse being different than the test data.

7. The memory system of claim 5, wherein the processing circuitry is configured to cause the memory system to determine the status of the repair scheme by being configured to cause the memory system to:
determine that components that implement the repair scheme are functional based at least in part on content read from the fuse matching the test data.

8. The memory system of claim 1, wherein the processing circuitry is further configured to cause the memory system to:
outputting a row flag that indicates a row of memory cells in the memory system, wherein the test mode flag is different than the row flag.

9. The memory system of claim 1, wherein the test mode flag comprises a first portion of a signal, and wherein a row flag comprises a second portion of the signal that is outputted after the first portion, the row flag indicating a row of memory cells in the memory system.

10. A memory system, comprising:
a repair latch associated with a redundant row of the memory system;
a first latch configured to output a first token signal;
a second latch configured to output a second token signal based at least in part on the first token signal; and
logic coupled with the first latch and the second latch and configured to select between the first token signal or the second token signal to pass to the repair latch, wherein the repair latch is configured to store an address for a defective row or test data based at least in part on the first token signal or the second token signal selected by the logic.

11. The memory system of claim 10, wherein the logic comprises:
a first logic gate configured to receive the first token signal, a first control signal that indicates a test mode for a repair scheme, and a second control signal that indicates a fuse that stores the test data for the repair scheme.

12. The memory system of claim 11, wherein the logic comprises:
a second logic gate configured to receive the second token signal, an inversion of the first control signal that indicates the test mode, and the second control signal that indicates the fuse.

13. The memory system of claim 12, wherein the logic comprises:
an OR gate comprising a first input node coupled with an output node of the first logic gate, and comprising a second input node coupled with an output node of the second logic gate.

14. The memory system of claim 12, wherein the first logic gate comprises a first AND gate, and wherein the second logic gate comprises a second AND gate.

15. The memory system of claim 10, further comprising:
second logic coupled with the first latch and the second latch and configured to select between the first token signal and the second token signal to pass to a second repair latch, wherein the second repair latch is configured to store a second address for a second defective row or second test data based at least in part on the first token signal or the second token signal selected by the second logic.

16. The memory system of claim 10, further comprising:
a data line coupled with a data input node of the repair latch, the data line configured to convey the test data and the address at different times.

17. A memory system, comprising:
processing circuitry associated with one or more memory devices and configured to cause the memory system to:
enter a test mode for testing a repair scheme of a memory system, wherein the repair scheme comprises replacing a defective row of the memory system with a redundant row of the memory system;
store, based at least in part on entering the test mode, test data in a fuse reserved for the test mode;
select, for passing to a repair latch corresponding to the redundant row and based at least in part on being in the test mode, between a first token signal outputted by a first latch and a second token signal outputted by a second latch; and
store the test data from the fuse in the repair latch based at least in part on passing the first token signal to the repair latch.

18. The memory system of claim 17, wherein the processing circuitry is further configured to cause the memory system to:
output the test data from the fuse to the repair latch corresponding to the redundant row of the memory system based at least in part on being in the test mode.

19. The memory system of claim 17, wherein the processing circuitry is further configured to cause the memory system to:
store, in the repair latch, an address of the defective row based at least in part on exiting the test mode, wherein storing the address overwrites the test data in the repair latch; and
select, after selecting the first token signal, the second token signal to pass to the repair latch, wherein the address is stored in the repair latch based at least in part on passing the first token signal to the repair latch.

20. The memory system of claim 17, wherein the first token signal is inputted into a clock input terminal of the repair latch based at least in part on selecting the first token signal, and wherein the test data is stored in the repair latch based at least in part on inputting the first token signal into the repair latch.
